(19) United States
(12) Patent Application Publication
(10) Pub. No.: US 2011/0300660 A1
(43) Pub. Date: Dec. 8, 2011

(54) METHOD OF MANUFACTURING PHOTOVOLTAIC DEVICE

(75) Inventor: Chui-Ling YIP, Hong Kong (HK)

(73) Assignee: Du Pont Apollo Limited, Hong Kong (HK)

(21) Appl. No.: 13/115,128

(22) Filed: May 25, 2011

Related U.S. Application Data
(60) Provisional application No. 61/351,937, filed on Jun. 7, 2010.

(51) Int. Cl. H01L 31/18

(52) U.S. Cl. 438/64; 257/E31.117

(57) ABSTRACT

Disclosed herein is a method of manufacturing a photovoltaic device. The method includes the steps of providing a front substrate and a back substrate, forming a photovoltaic cell on the front substrate, encapsulating the photovoltaic cell by an encapsulant, attaching a solid state sealant tape on one of the two substrates, and adhering the two substrates through the solid state sealant tape and the encapsulant. The solid state sealant tape is in solid state at room temperature. The photovoltaic cell and the encapsulant are situated within an enclosed space formed by the two substrates and the solid state sealant tape.

### RELATED APPLICATIONS

This application claims priority to U.S. Provisional Application Ser. No. 61/351,937, filed Jun. 7, 2010, which is herein incorporated by reference.

### BACKGROUND

1. Technical Field

The present disclosure relates to a method of manufacturing an energy conversion device. More particularly, the present disclosure relates to a method of manufacturing a photovoltaic device.

2. Description of Related Art

In the trend of green technology, solar energy has gained many research attentions for being a seemingly inexhaustible energy source. For such purpose, photovoltaic (PV) devices that convert light energy, particularly sunlight, into electrical energy are developed. Particularly, no greenhouse gas is produced during the energy conversion process, and the electrical energy generated by the PV devices can be used for all kinds of applications as those achieved by batteries or existing power generators. For such reasons, the PV devices are getting more and more popular in the market and are now widely used in various electronic products.

Typically, the PV device includes two parallel substrates, a photovoltaic cell disposed between the two substrates and a sealant that seals the internal space of the PV device. In one common manufacturing process, the PV cell is deposited on one substrate by chemical vapor deposition (CVD), physical vapor deposition (PVD), or plasma-enhanced chemical vapor deposition (PECVD). After the PV cell is deposited, an encapsulant is provided to encapsulate the PV cell, and the two substrates are adhered to one another by use of a liquid sealant. The liquid sealant is dispensed on the substrate by a dispensing mechanism (a device, an equipment, or a machine), so as to control the dimension and orientation of the liquid sealant.

Due to the fact that the sealant is in liquid form, the positioning and the dimension of the liquid sealant are difficult to control. The dispensing mechanism requires precise and stable flow rate, which increases the investment cost to facilities. Moreover, after the liquid sealant is dispensed, a curing process is needed to solidify the sealant to form a firm sealing between the two substrates. The curing process is time consuming and may prolong the manufacturing cycle time, which relatively raises the product cost.

### SUMMARY

A method of manufacturing a photovoltaic device is provided. The method utilizes a solid state sealant tape to seal the front and the back substrate and at least has the merits of simplifying the handling process with manual operation or with the help of robotic processing, increasing the manufacturing efficiency, and reducing the cost.

According to one aspect of the disclosure, the method of manufacturing a photovoltaic device includes the steps of providing a front substrate and a back substrate, forming a photovoltaic cell on the front substrate, encapsulating the photovoltaic cell by an encapsulant, attaching a solid state sealant tape that is in solid state at room temperature on one of the two substrates, and adhering the front substrate to the back substrate by the solid state sealant tape and the encapsulant so that the photovoltaic cell and the encapsulant are situated within an enclosed space formed by the two substrates and the solid state sealant tape.

In one embodiment, the step of adhering the two substrates includes the steps of aligning the back substrate with the front substrate, applying a pressure to the aligned back substrate and the front substrate, and heating the aligned back substrate and the front substrate so that the two substrates are adhered with each other through the solid state sealant tape and the encapsulant.

In another embodiment, the step of attaching the solid state sealant tape on one of the two substrates, the solid state sealant tape is attached to a peripheral area on one of the two substrates surrounding the photovoltaic cell and the encapsulant. The solid state sealant tape includes a number of strips. The step of attaching the solid state sealant tape includes a step of attaching the strips in the peripheral area to completely surround the photovoltaic cell and the encapsulant. The strips are partially overlapped with each other, or are connected to each other in parallel.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiments, with reference made to the accompanying drawings as follows:

FIG. 1 is a flow chart of a method of manufacturing a photovoltaic device according to one embodiment of the disclosure; and

FIGS. 2A-2I are different perspective views of the photovoltaic device in accordance with the steps of FIG. 1 respectively.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

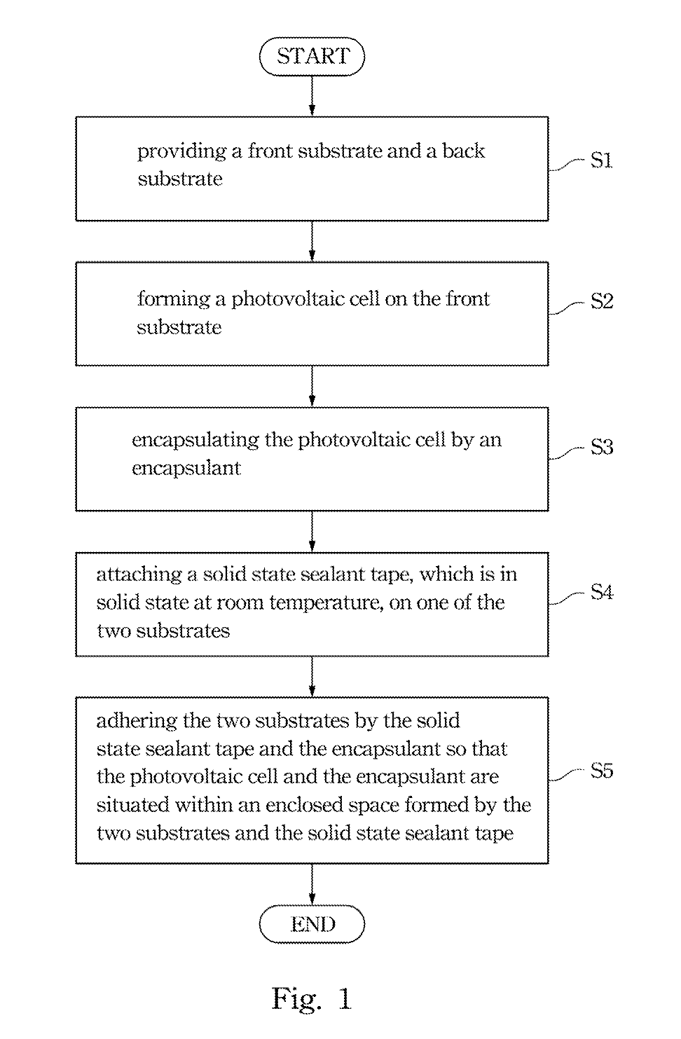

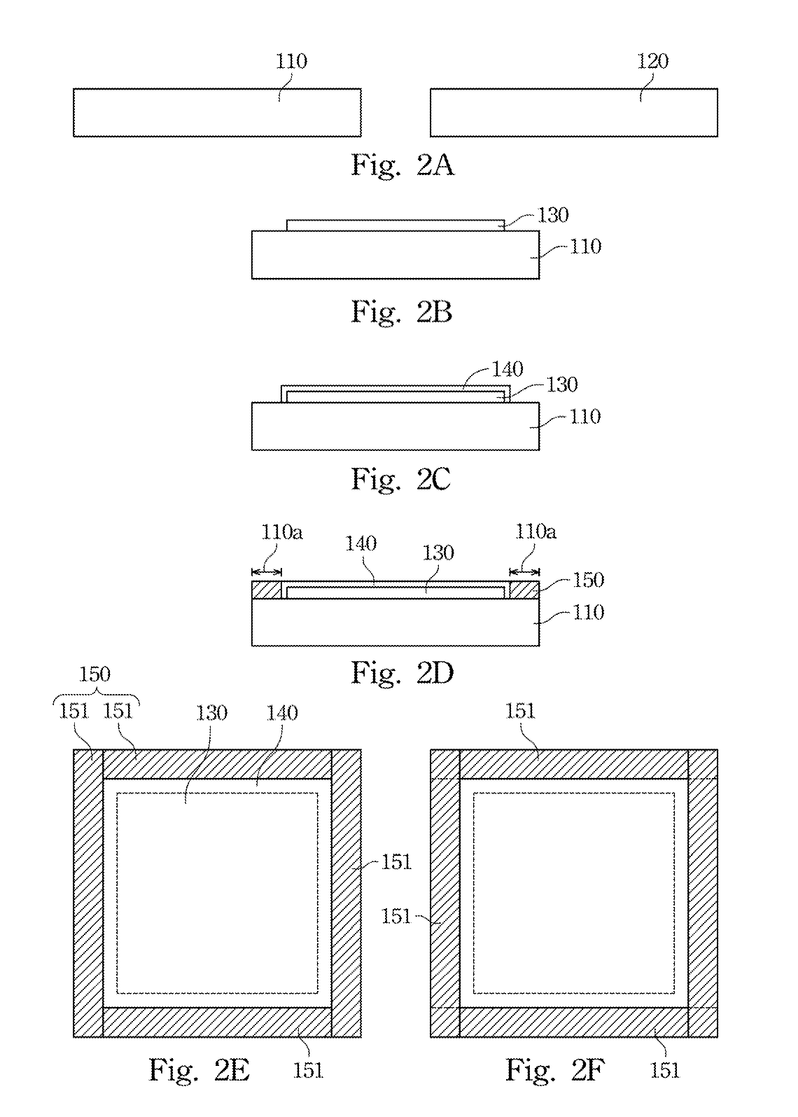

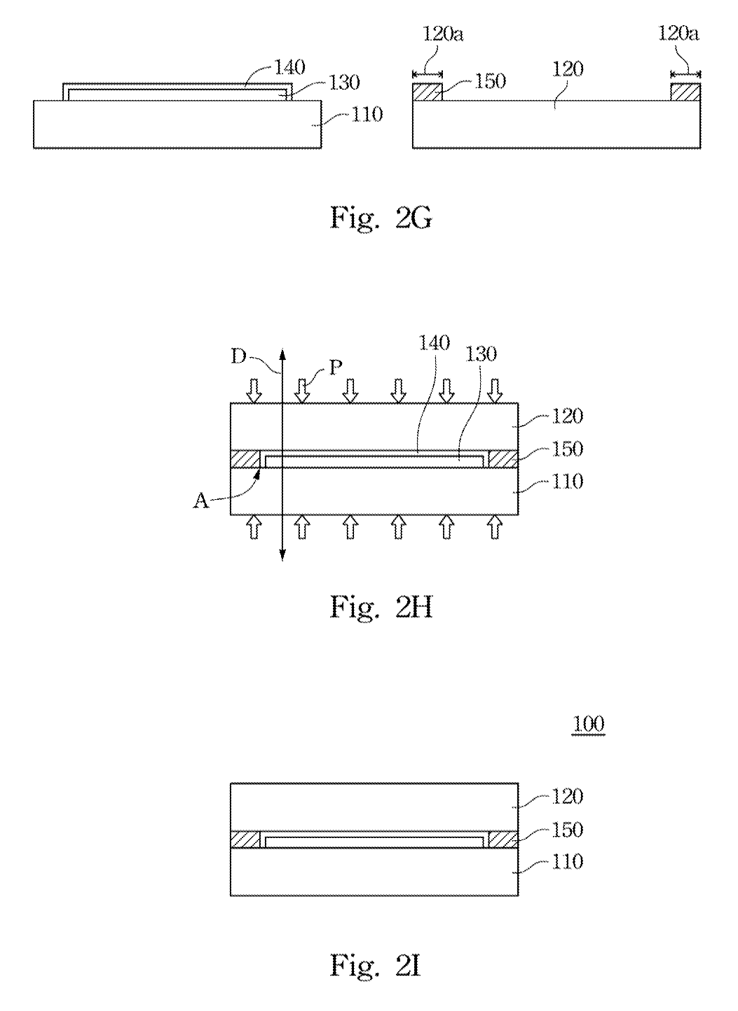

FIG. 1 is a flow chart of a method of manufacturing a photovoltaic device according to one embodiment of the disclosure. FIGS. 2A-2I are different perspective views of the photovoltaic device in accordance with the steps of FIG. 1 respectively.

First in the method, as shown in step S1 with reference to FIG. 2A, a front substrate 110 and a back substrate 120 are provided. In one embodiment, the front substrate 110 and the back substrate 120 are glass substrates, such as transparent conductive oxide (TCO) coated glass substrates. However, the technology of the disclosure is not limited to glass substrates; other appropriate substrates may be adopted as well. For example, the front substrate 110 or the back substrate 120 may also be a polymeric sheet, such as a DuPont™ Teflon® film, a DuPont™ Teonex® polyethylene naphthalate (PEN) film, and a DuPont™ Melinex® ST polyester film. Moreover, the front substrate 110 and the back substrate 120 may both be polymeric sheets.

Next, step S2 is performed to form a photovoltaic cell 130 on the front substrate 110. An exemplarily disposition of the photovoltaic cell 130 on the front substrate 110 is depicted in FIG. 2B. The photovoltaic cell 130 can be exemplified by a thin film photovoltaic cell having a first conductive electrode layer, energy conversion layers, a second conductive electrode layer deposited on the front substrate 110. Exemplary materials of the energy conversion layers include, but are not limited to, amorphous silicon, cadmium diselenide (CdS), cadmium telluride (Cd/Te), copper indium diselenide (CIS), and/or copper indium gallium diselenide (CMS). The photovoltaic cell 130 may be deposited by appropriate depositing methods, such as chemical vapor deposition (CVD), physical vapor deposition (PVD), plasma-enhanced chemical vapor deposition (PECVD), sputtering, or any other methods known to a person skilled in the art. The above-mentioned materials and methods are for exemplifications only, and are not intended to limit the scope of the disclosure.

After forming the photovoltaic cell 130, the method moves on to step S3, encapsulating the photovoltaic cell by an encapsulant 140. As depicted in FIG. 2C, the to encapsulant 140 fully covers the photovoltaic cell 130, so as to prevent moisture corrosion and oxidation of the photovoltaic cell 130. In other words, the area of the encapsulant 140 is the same as that of the photovoltaic cell 130; alternatively, the area of the encapsulant 140 is greater than that of the photovoltaic cell 130. Suitable material of the encapsulant 140 can be selected in accordance with actual product needs. For example, the encapsulant 140 may be commercially obtainable DuPont™ Elvax® ethyl vinyl acetate (EVA) resins, commercially obtainable DuPont™ PV5200 series encapsulant sheets, commercially obtainable DuPont™ PV5300 series encapsulant sheets, or other appropriate polymeric materials. The above-mentioned materials are for exemplifications only, and are not intended to limit the scope of the disclosure.

The method of manufacturing the photovoltaic device now moves on to step S4, attaching a solid state sealant tape 150 on one of the two substrates. As depicted in FIG. 2D, the solid state sealant tape is attached on the front substrate 110 in the present embodiment. The solid state sealant tape 150 is in solid state at room temperature, around 25° C. for example, and includes a base polymer made of butyl rubber or polyisobutylene. The thickness of the solid state sealant tape 150 is approximately the same as the height of the photovoltaic cell 130 with the encapsulant 140.

The solid state sealant tape 150 is attached to a peripheral area on one of the two substrates surrounding the photovoltaic cell 130 and the encapsulant 140. More specifically, as depicted in FIG. 2D and FIG. 2E, the solid state sealant tape 150 is attached to the peripheral area 110a on the front substrate 110, and is configured to completely surround the photovoltaic cell 130 and the encapsulant 140. In the present embodiment, the solid state sealant tape 150 includes a number of strips 151 that are attached to the front substrate 110 in a way of connecting to each other in parallel. Each two adjacent strips 151 are closely aligned with each other, after melting the strips 150, a continuous loop of the solid state sealant tape 150 as a barrier to resist damage in outdoor and UV exposure is formed.

Although the strips 151 of the solid state sealant tape 150 are exemplified by connecting to each other in parallel, the disposition of the strips 151 are not limited thereto. In another embodiment, the strips 151 can be partially overlapped with each other. As depicted in FIG. 2F, each strip 151 is partially covered by another adjacent strip 151, especially near the two distal ends of each strip 151, so as to eliminate the possibility of forming gaps between two adjacent strips 151.

The above-described solid state sealant tape 150 is exemplified by attaching on the front substrate 110; alternatively, in another embodiment, the solid state sealant tape 150 is attached on the back substrate 120 according to the demands. As depicted in FIG. 2G, the solid state sealant tape 150 is attached to the peripheral area 120a on the back substrate 120 surrounding the photovoltaic cell 130. When the front substrate 110 and the back substrate 120 are assembled in the subsequent steps, the solid state sealant tape 150 completely surrounds the photovoltaic cell 130 and the encapsulant 140. The details of the disposition of the solid state sealant tape 150 on the back substrate 120 are similar to that on the front substrate 110, and will not be repeated here.

Practically, the solid state sealant tape 150 can be attached manually or by robotic machines, which increases the flexibility of the manufacturing process. Further, by manually attaching the solid state sealant tape 150, the manufacturing facility is simplified and the cost is reduced accordingly. Moreover, the dimension and the attaching directions of the solid state sealant tape 150 can be precisely controlled.

Following the completion of step S4, steps S5 is performed according to the method of the present embodiment. In step S5, the front substrate 110 and the back substrate 120 are adhered to one another by the solid state sealant tape 150 and the encapsulant 140 so that the photovoltaic cell 130 and the encapsulant 140 are situated within an enclosed space formed by the two substrates 110 and 120 and the solid state sealant tape 150.

In order to firmly adhere the two substrates 110 and 120, step S5 may be performed according to the following sub-steps with reference to FIG. 2H. First, the back substrate 120 is aligned with the front substrate 110. Next, a pressure P is applied to the aligned back substrate 120 and the front substrate 110. Then, the two substrates 110 and 120 are heated so that they are adhered with each other through the solid state sealant tape 150. The pressure P is about 101 kPa and is applied bi-directionally in the upright directions D of the two substrates 110 and 120. The solid state sealant tape 150 is therefore firmly pressed against the two substrates 110 and 120 and is in tight contact with the two substrates 110 and 120. With the pressure P applied to the back substrate 120 and the front substrate 110, the two substrates 110,120 and the solid state sealant tape 150 are heated to about 140-160° C. As a result, the solid state sealant tape 150 slightly melts into a semi-solid state to form air-tight sealing with the front substrate 110 and the back substrate 120 respectively. With this regard, only the superficial portion of the solid state sealant tape 150 needs to be melted to adhere to the two substrates 110 and 120, instead of melting it entirely, the heating time is minimized and the thermal damage to the photovoltaic cell 130 is alleviated.

More specifically, the encapsulant 140 also facilitates the adhesion of the two substrates 110 and 120. Once the two substrates 110, 120 are adhered, the enclosed space A is formed among the front substrate 110, the back substrate 120, and the solid state sealant tape 150. The photovoltaic cell 130 and the encapsulant 140 are situated within the enclosed space A.

As shown in FIG. 21, the photovoltaic device 100 according to one embodiment of the disclosure is completed after the front substrate 110 and the back substrate 120 are adhered to one another. By using the solid state sealant tape 150 and the encapsulant 140 in the photovoltaic device 100, the water resistivity is enhanced in comparison with known liquid state sealant. According to a test result, the photovoltaic device 100 with solid state sealant tape 150 made of polyisobutylene (MB) or butyl rubber has a water penetration rate lower than 0.01 to 0.6 g/cm² per day. The water leakage resistivity of the photovoltaic device 100 is larger than 70 mega ohms and maintains in a stable state for more than 1000 hours when the solid state sealant tape 150 is used.

In the above-described method of manufacturing a photovoltaic device, the solid state sealant tape is used to realize a simple and precise way of disposing the sealant. The dimension and the attaching orientations can be precisely controlled, so as to increase the product quality. Further, the solid state sealant tape can be attached manually or by robotic machines, which increases the flexibility of the manufacturing process. In the step of heating the substrates and the solid state sealant tape, the solid state sealant tape needs not to be heated entirely, which reduces the heating time and alleviates the thermal damage to the photovoltaic cell.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing a photovoltaic device, comprising:
providing a front substrate and a back substrate;
forming a photovoltaic cell on the front substrate;
encapsulating the photovoltaic cell by an encapsulant;
attaching a solid state sealant tape, which is in solid state at room temperature, on one of the front and back substrates; and
adhering the front substrate to the back substrate by the solid state sealant tape and the encapsulant so that the photovoltaic cell and the encapsulant are situated within an enclosed space formed by the front and back substrates and the solid state sealant tape.

2. The method of claim 1, wherein the step of adhering the front substrate and the back substrate comprises:
aligning the back substrate with the front substrate;
applying a pressure to the aligned back substrate and the front substrate; and
heating the aligned back substrate and the front substrate so that the front and back substrates are adhered with each other through the solid state sealant tape and the encapsulant.

3. The method of claim 2, wherein the front and back substrates are heated to about 140-160° C.

4. The method of claim 2, wherein the pressure is applied bi-directionally in the upright directions of the front and back substrates and is about 101 kPa.

5. The method of claim 1, wherein in the step of attaching the solid state sealant tape on one of the front and back substrates, the solid state sealant tape is attached to a peripheral area on one of the front and back substrates surrounding the photovoltaic cell and the encapsulant.

6. The method of claim 5, wherein the solid state sealant tape comprises a plurality of strips and the step of attaching the solid state sealant tape on one of the front and back substrates comprises:
attaching the strips in the peripheral area to completely surround the photovoltaic cell and the encapsulant.

7. The method of claim 6, wherein the strips are partially overlapped with each other.

8. The method of claim 6, wherein the strips are connected to each other in parallel.

9. The method of claim 1, wherein the solid state sealant tape comprises a base polymer made of butyl rubber.

10. The method of claim 1, wherein the solid state sealant tape comprises a base polymer made of polyisobutylene.

11. The method of claim 1, wherein each substrate is a glass substrate or a polymeric sheet.

12. The method of claim 1, wherein the thickness of the solid state sealant tape is approximately the same as the height of the photovoltaic cell with the encapsulant.
